(19) United States
(12) Patent Application Publication
(10) Pub. No.: US 2026/0156851 A1
(43) Pub. Date: Jun. 4, 2026

(54) SEMICONDUCTOR DEVICE AND METHOD FOR MANUFACTURING SEMICONDUCTOR DEVICE

(71) Applicants: HYUNDAI MOTOR COMPANY, Seoul (KR); KIA CORPORATION, Seoul (KR)

(72) Inventors: Nack Yong JOO, Hwaseong-si (KR); Dae Hwan CHUN, Hwaseong-si (KR); Jungyeop HONG, Hwaseong-si (KR); Taehyun KIM, Hwaseong-si (KR); Youngkyun JUNG, Hwaseong-si (KR); Junghee PARK, Hwaseong-si (KR)

(21) Appl. No.: 19/391,404

(22) Filed: Nov. 17, 2025

(30) Foreign Application Priority Data
Dec. 4, 2024 (KR) 10-2024-0178186

(51) Int. Cl. H10D 12/00; H10D 12/01

(52) U.S. Cl. CPC H10D 12/411; H10D 12/031

(57) ABSTRACT

A semiconductor device and a method for manufacturing the semiconductor device are provided. The semiconductor device includes a substrate, an n− type epitaxial layer on the substrate, a p type base layer on the n− type epitaxial layer, an n+ type layer within the p type base layer, a p+ type layer adjacent to the n+ type layer within the p type base layer, an insulating layer on the n− type epitaxial layer, a gate on the insulating layer, and a collector on the insulating layer. The p+ type layer includes a first p+ type layer disposed in one side region of the semiconductor device and a second p+ type layer disposed in the other side region of the semiconductor device.

### CROSS-REFERENCE TO RELATED APPLICATION

This application claims priority to and the benefit of Korean Patent Application No. 10-2024-0178186 filed at the Korean Intellectual Property Office on Dec. 4, 2024, the entire contents of which are incorporated herein by reference.

### TECHNICAL FIELD

The present disclosure relates to a semiconductor device and a method for manufacturing the semiconductor device, and more particularly, to a diode-connected collector lateral insulated gate bipolar transistor (IGBT).

### BACKGROUND

Transistor devices such as metal-oxide-semiconductor field-effect transistors (MOSFETs), junction field-effect transistors (JFETs), metal-semiconductor field-effect transistors (MESFETs), and insulated gate bipolar transistors (IGBTs) are three-terminal devices capable of conducting current by controlling the gate terminal. In particular, power semiconductor transistors for switching require high voltage and high current. Transistor devices have different electrical characteristics depending on their structure, and appropriate devices are selected depending on the application. In some cases, transistor devices require high current density, low turn-on voltage, high breakdown voltage, low leakage current, and fast switching speed. These electrical characteristics are in a trade-off relationship, and structures are continuously being researched to improve one or more characteristics while maintaining other characteristics by weakening this trade-off relationship.

In particular, IGBTs, which are mainly used in three-phase inverters, may reduce resistance by utilizing the conductivity modulation effect through high-level injection of minority carriers to improve the resistance of the N-epi region, which is a high-resistance region. However, the problem of reduced switching speed may occur because the injection and removal speed of minority carriers is limited by high-level injection.

### SUMMARY

Aspects of the present disclosure provide a semiconductor device having a structure capable of improving switching speed while maintaining conductivity modulation effect, and a method for manufacturing the semiconductor device.

A semiconductor device according to an implementation includes a substrate, an n− type epitaxial layer on the substrate, a first p type base layer on the n− type epitaxial layer and in one side region of the semiconductor device, a second p type base layers on the n− type epitaxial layer and in the other side region of the semiconductor device, a first n+ type layers within the first p type base layer and in the one side region of the semiconductor device, a second n+ type layers within the second p type base layer and in the other side region of the semiconductor device, a first p+ type layer adjacent to the first n+ type layer within the first p type base layer and in the one side region of the semiconductor device, a second p+ type layer adjacent to the second n+ type layer within the second p type base layer and in the other side region of the semiconductor device, an insulating layer on the n− type epitaxial layer, a gate on the insulating layer, at least a portion of the first p type base layer, and a portion of the first n+ type layer, and a collector on the insulating layer, at least a portion of the second p type base layer, and at least a portion of the second n+ type layer.

In some implementations, the first n+ type layer can be disposed between the first p type base layer and the first p+ type layer, and the second n+ type layer can be disposed between the second p type base layer and the second p+ type layer.

In some implementations, one side surface of the first n+ type layer can be in contact with the first p+ type layer, and the other side surface of the first n+ type layer, the lower surface of the first n+ type layer, and the lower surface of the first p+ type layer can be in contact with the first p type base layer.

In some implementations, one side surface of the second n+ type layer, the lower surface of the second n+ type layer and the lower surface of the second p+ type layer can be in contact with the second p type base layer, and the other side surface of the second n+ type layer can be in contact with the second p+ type layer.

In some implementations, the lower surface of the insulating layer can be in contact with a portion of the upper surface of the first n+ type layer, the uppermost surface of the first p type base layer, the uppermost surface of the second p type base layer, and a portion of the upper surface of the second n+ type layer.

In some implementations, the semiconductor device can further include an emitter, wherein a portion of the lower surface of the emitter can be in contact with a portion of the upper surface of the first n+ type layer and the upper surface of the first p+ type layer.

In some implementations, a portion of the lower surface of the collector can be in contact with the upper surface of the insulating layer, and another portion of the lower surface of the collector can be in contact with a portion of the upper surface of the second n+ type layer and the upper surface of the second p+ type layer.

In some implementations, the gate can be covered with a passivation layer, and the collector may not be covered with the passivation layer.

In some implementations, the gate and the collector can be covered with the passivation layer, and the lower surface of the collector can be in contact with the upper surface of the insulating layer.

In some implementations, the semiconductor device can further include an additional collector, wherein a portion of the lower surface of the additional collector can be in contact with the upper surface of the passivation layer, and another portion of the lower surface of the additional collector can be in contact with a portion of the upper surface of the second n+ type layer and the upper surface of the second p+ type layer.

A method for manufacturing a semiconductor device according to an implementation includes forming an n− type epitaxial layer on the substrate, forming a first p type base layer on the n− type epitaxial layer and in one side region of the semiconductor device, forming a second p type base layer on the n− type epitaxial layer and in the other side region of the semiconductor device, forming a first n+ type layer on the first p type base layer and in the one side region of the semiconductor device, forming a second n+ type layer on the second p type base layer and in the other side region of the semiconductor device, forming a first p+ type layer adjacent to the first n+ type layer within the first p type base layer and in the one side region of the semiconductor device, forming a second p+ type layer adjacent to the second n+ type layer within the second p type base layer and in the other side region of the semiconductor device, forming an insulating layer on the n− type epitaxial layer, on the insulating layer, forming a gate on at least a portion of the first p type base layer and a portion of the first n+ type layer; and on the insulating layer, forming a collector on at least a portion of the second p type base layer and at least a portion of the second n+ type layer.

In some implementations, the first n+ type layer can be disposed between the first p type base layer and the first p+ type layer, and the second n+ type layer can be disposed between the second p type base layer and the second p+ type layer.

In some implementations, one side surface of the first n+ type layer can be in contact with the first p+ type layer, and the other side surface of the first n+ type layer, the lower surface of the first n+ type layer, and the lower surface of the first p+ type layer can be in contact with the first p type base layer.

In some implementations, one side surface of the second n+ type layer, the lower surface of the second n+ type layer and the lower surface of the second p+ type layer can be in contact with the second p type base layer, and the other side surface of the second n+ type layer can be in contact with the second p+ type layer.

In some implementations, the lower surface of the insulating layer can be in contact with a portion of the upper surface of the first n+ type layer, the uppermost surface of the first p type base layer, the uppermost surface of the second p type base layer, and a portion of the upper surface of the second n+ type layer.

In some implementations, the method for manufacturing the semiconductor device can further include forming an emitter, wherein a portion of the lower surface of the emitter can be in contact with a portion of the upper surface of the first n+ type layer and the upper surface of the first p+ type layer.

In some implementations, a portion of the lower surface of the collector can be in contact with the upper surface of the insulating layer, and another portion of the lower surface of the collector can be in contact with a portion of the upper surface of the second n+ type layer and an upper surface of the second p+ type layer.

In some implementations, the gate can be covered with the passivation layer, and the collector may not be covered with the passivation layer.

In some implementations, the gate and the collector can be covered with the passivation layer, and the lower surface of the collector can be in contact with the upper surface of the insulating layer.

In some implementations, the method for manufacturing the semiconductor device can further include forming the additional collector, wherein a portion of the lower surface of the additional collector can be in contact with the upper surface of the passivation layer, and another portion of the lower surface of the additional collector can be in contact with a portion of the upper surface of the second n+ type layer and an upper surface of the second p+ type layer.

### BRIEF DESCRIPTION OF THE DRAWINGS

FIG. 1 illustrates a semiconductor device according to an example of the present disclosure.

FIGS. 2 and 3 illustrate an example operating mechanism of a semiconductor device according to an example of the present disclosure.

FIG. 4 illustrates a method for manufacturing a semiconductor device according to an example of the present disclosure.

FIG. 5 illustrates a method for manufacturing a semiconductor device according to an example of the present disclosure.

FIG. 6 illustrates a semiconductor device according to an example of the present disclosure.

FIG. 7 illustrates a method for manufacturing a semiconductor device according to an example of the present disclosure.

FIG. 8 illustrates a method for manufacturing a semiconductor device according to an example of the present disclosure.

FIGS. 9 to 11 illustrate the characteristics of a semiconductor device according to example of the present disclosure.

### DETAILED DESCRIPTION

The present disclosure will be described in detail hereinafter with reference to the accompanying drawings, in which implementations of the present disclosure are shown. As those skilled in the art would realize, the described implementations may be modified in various different ways, all without departing from the spirit or scope of the present disclosure. The drawings and description are to be regarded as illustrative in nature and not restrictive, and like reference numerals designate like elements throughout the specification.

Although the terms “first,” “second,” and the like are used to explain various components, the components are not limited to such terms. These terms are only used to distinguish one component from another component.

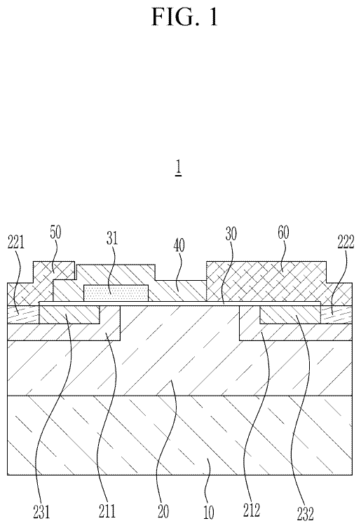

FIG. 1 illustrates a semiconductor device according to an example of the present disclosure.

Referring to FIG. 1, a semiconductor device 1 according to an implementation may include a substrate 10, an n− type epitaxial layer 20, p type base layers 211 and 212, p+ type layers 221 and 222, n+ type layers 231 and 232, an insulating layer 30, a gate 31, a passivation layer 40, an emitter 50, and a collector 60.

The semiconductor device can be implemented as an IGBT device. IGBTs are power semiconductor devices suitable for high voltage and high current control, and can have a structure that combines the high input impedance of metal-oxide-semiconductor field-effect transistors (MOSFETs) and the low conduction loss characteristics of bipolar junction transistors (BJTs). IGBTs can control current through a metal-oxide-semiconductor (MOS) gate, which can provide high current density and conduction efficiency through a BJT-based output structure. Due to these characteristics, IGBTs can have low switching loss and high power conversion efficiency, allowing them to be widely used in a variety of high-power applications, such as inverters, converters, and power control devices.

The substrate 10 can be a semi-insulating substrate or an insulating substrate. The semi-insulating substrate can be a semiconductor material with high electrical resistance, which can have properties between a conductive semiconductor and a completely insulating insulator. On the other hand, the insulating substrate can have electrically insulating properties. In some implementations, the semi-insulating substrate can be made of gallium arsenide (GaAs), silicon carbide (SiC), or the like, and the insulating substrate can be made of sapphire, glass, a silicon-on-insulator (SOI) substrate, or the like. The n− type epitaxial layer 20 can be formed on the substrate 10.

The p type base layers 211 and 212 can be formed on the n− type epitaxial layer 20. The p type base layers can include a first p type base layer 211 and a second p type base layer 212. The p type base layers 211 and 212 can be formed by patterning a p− base region on the n− type epitaxial layer 20, then injecting p type dopant ions, such as boron, into the region and diffusing and activating them through a subsequent heat treatment process. In this process, the desired p− base region can be precisely patterned using photolithography technology. The p type base layers 211 and 212 can form a PN junction with the n− type epitaxial layer 20.

The n+ type layers 231 and 232 can be formed within the p type base layers 211 and 212. The n+ type layers 231 and 232 can include a first n+ type layer 231 and a second n+ type layer 232. The n+ type layers 231 and 232 can be formed by patterning an n+ region on the p type base layers 211 and 212, then injecting n type dopant ions, such as phosphorus and/or arsenic, into the region, and diffusing and activating them through a subsequent heat treatment process.

The p+ type layers 221 and 222 can be formed adjacent to the n+ type layers 231 and 232 within the p type base layers 211 and 212. The p+ type layers 221 and 222 can be formed by patterning a p+ region on the p type base layers 211 and 212 and at the same layer level as the n+ type layers 231 and 232, then injecting p type dopant ions, such as boron, into the region, and diffusing and activating them through a subsequent heat treatment process.

The insulating layer 30 can be formed on the n− type epitaxial layer 20. This can be achieved through a gate oxide layer deposition process. The gate oxide layer can be formed of silicon oxide (SiO₂) through a thermal oxidation or chemical vapor deposition (CVD) process.

The gate 31 can be formed on the insulating layer 30, and can be formed on at least a portion of the first p type base layer 211 disposed in one side region of the semiconductor device 1, and on a portion of the first n+ type layer 231 disposed in one side region of the semiconductor device 1. The gate 31 can be formed of polysilicon, and a metal material can be used as needed.

The collector 60 can be formed on the insulating layer 30, and can be formed on at least a portion of the second p type base layer 212 disposed in the other side region of the semiconductor device 1, and on at least a portion of the second n+ type layer 232 disposed in the other side region of the semiconductor device 1.

The p+ type layers 221 and 222 can include a first p+ type layer 221 disposed in one side region of the semiconductor device 1 and a second p+ type layer 222 disposed in the other side region of the semiconductor device 1.

In some implementations, the first n+ type layer 231 can be formed to be disposed between the first p type base layer 211 and the first p+ type layer 221, and the second n+ type layer 232 can be formed to be disposed between the second p type base layer 212 and the second p+ type layer 222.

In some implementations, one side surface of the first n+ type layer 231 can be in contact with the first p+ type layer 221. The other side surface of the first n+ type layer 231, the lower surface of the first n+ type layer 231, and the lower surface of the first p+ type layer 221 can be in contact with the first p type base layer 211. One side surface of the second n+ type layer 232, the lower surface of the second n+ type layer 232, and the lower surface of the second p+ type layer 222 can be in contact with the second p type base layer 212. The other side surface of the second n+ type layer 232 can be in contact with the second p+ type layer 222.

The lower surface of the insulating layer 30 can be in contact with a portion of the upper surface of the first n+ type layer 231, the uppermost surface of the first p type base layer 211, the uppermost surface of the second p type base layer 212, and a portion of the upper surface of the second n+ type layer 232.

In some implementations, a portion of the lower surface of the emitter 50 can be in contact with a portion of the upper surface of the first n+ type layer 231 and the upper surface of the first p+ type layer 221.

In some implementations, a portion of the lower surface of the collector 60 can be in contact with the upper surface of the insulating layer 30, and another portion of the lower surface of the collector 60 can be in contact with a portion of the upper surface of the second n+ type layer 232 and the upper surface of the second p+ type layer 222.

Additionally, in the some implementations, the gate 31 can be formed to be covered with the passivation layer 40, and the collector 60 can be formed to not be covered with the passivation layer 40.

In structures of the related art, the IGBT inevitably has a knee voltage due to the built-in voltage generated at the PN junction in the collector region, resulting in a region that does not conduct even though the gate is on. In addition, the conductivity modulation phenomenon utilized to reduce on-resistance may cause a decrease in switching speed and an increase in switching loss due to minority carriers. In addition, in the lateral IGBT structure of the related art, the voltage applied to the collector terminal is concentrated in the gate corner area adjacent to the collector, which frequently causes the gate oxide layer to be destroyed. Aspects of the present disclosure can address these problems, and can advantageously reduce the knee voltage and hole current density and increase the on-state current density and breakdown voltage compared to the IGBT structures of the related art.

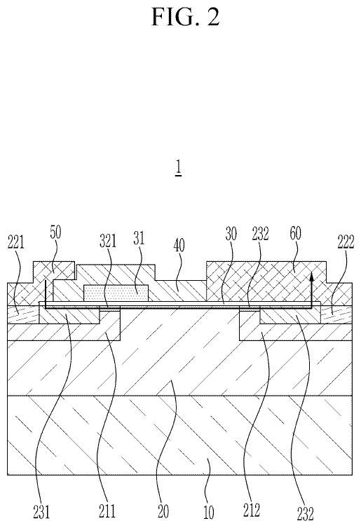

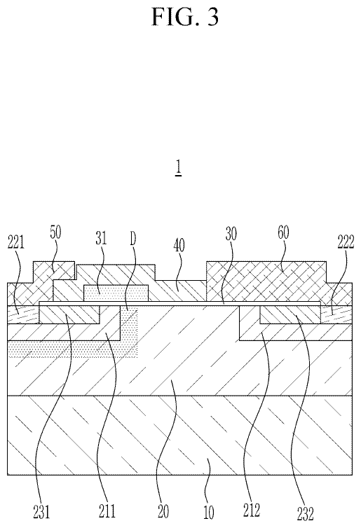

FIGS. 2 and 3 illustrate the operating mechanism of a semiconductor device 1 according to an example of the present disclosure.

FIG. 2 shows the channel formation structure and electron movement path in the on-state of the semiconductor device 1, and FIG. 3 shows the distribution of a depletion layer D in the off-state of the semiconductor device 1.

In some implementations, the semiconductor device 1 can have a first on-state, a second on-state, and an off-state. The first on-state represents the case where the collector-emitter voltage (V_{CE})) is within the range O≤V_{CE}≤Vₖₙₑₑ and the gate-emitter voltage (V_{GE}) is Vₜₕ≤V_{GE}. Here, V_{CE} is the voltage applied between collector-emitter terminals, and V_{GE} is the voltage applied between gate-emitter terminals.

Vₖₙₑₑ is the minimum V_{CE} voltage for the IGBT device to conduct, and Vₜₕ is the minimum V_{GE} voltage for the IGBT device to conduct. In this state, an inversion channel can be formed in the MOS structure at the bottom of the collector terminal, so no current is conducted. This might be because Vₖₙₑₑ is determined by Vₜₕ at which the inversion channel is formed in the MOS structure and an intrinsic voltage V_{bi} of the PN junction. Here, V_{bi} is the minimum voltage for the PN junction to turn on.

The second on-state represents the case where V_{CE} is Vₖₙₑₑ≤V_{CE} and V_{GE} is Vₜₕ≤V_{GE}. In this state, a channel can be formed in the MOS structure at the bottom of the collector terminal to conduct current, which can flow in the following sequence: emitter terminal→N+ emitter→inversion channel in the P-base of the emitter terminal→N− epitaxial layer→inversion channel in the P-base of the collector terminal→N+ collector→collector terminal. In this process, electron current and hole current can flow together, and the ratio of electron current to hole current in the total current can be controlled by adjusting Vₖₙₑₑ and V_{bi}.

The off state represents the case where V_{CE} is 0≤V_{CE}, and V_{GE} is Vₜₕ≥V_{GE}. When 0≤V_{CE}≤Vₖₙₑₑ, the current can be blocked by each PN junction between the emitter terminal and the collector terminal, and when Vₖₙₑₑ≤V_{CE}, an inversion channel can be formed within the P-base of the collector terminal, but the current can be blocked by the PN junction of the emitter terminal. In this state, the collector voltage may not be directly applied to the N-epitaxial layer, which can reduce the electric field concentrated in the gate region.

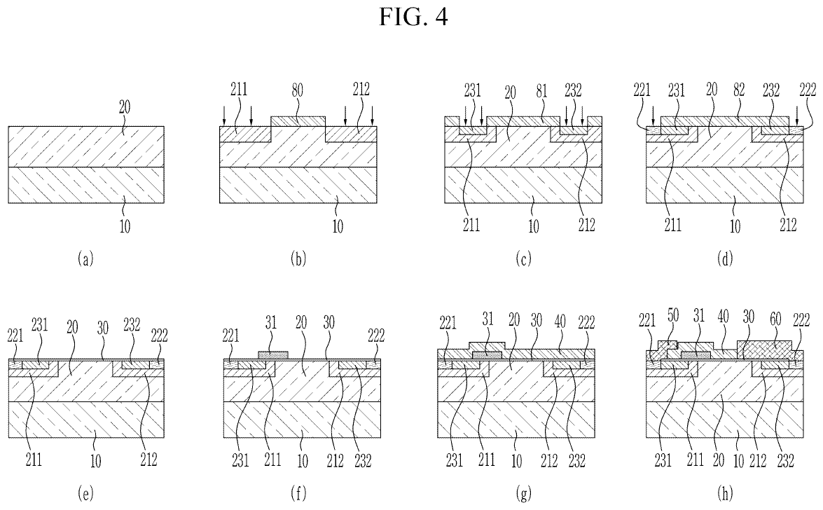

FIG. 4 illustrates a method for manufacturing a semiconductor device according to an example of the present disclosure.

As shown in FIG. 4, in (a), the substrate 10 and the n− type epitaxial layer 20 can be formed, and in (b), the p− base region can be patterned on the n− type epitaxial layer 20, and then p type dopant ions can be injected to form the p type base layers 211 and 212. In (c), the n+ type layers 231 and 232 can be formed by patterning an n+ region on the p type base layers 211 and 212 and then injecting n+ type dopant ions. In (d), after patterning the p+ region on the p type base layers 211 and 212 and at the same layer level as the n+ type layers 231 and 232, the same p type dopant ions can be injected so that the p+ type layers 221 and 222 can be formed adjacent to the n+ type layers 231 and 232 within the p type base layers 211 and 212. In (e), the insulating layer 30 can be formed through a gate oxide layer deposition process, and in (f), the gate 31 can be formed through patterning after polysilicon deposition. In (g), the passivation layer 40 can be deposited, and the emitter 50 and the collector 60 can be formed, wherein a portion of the lower surface of the collector 60 can be in contact with the upper surface of the insulating layer 30, and another portion of the lower surface of the collector 60 can be in contact with a portion of the upper surface of the second n+ type layer 232 and the upper surface of the second p+ type layer 222. The gate 31 can be formed to be covered with the passivation layer 40, and the collector 60 can be formed not to be covered with the passivation layer 40.

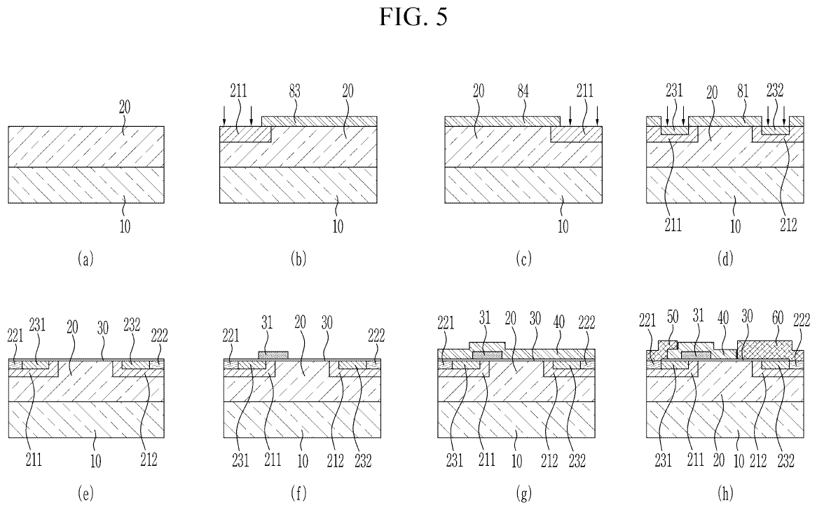

FIG. 5 illustrates a method for manufacturing a semiconductor device according to an example of the present disclosure.

Referring to FIG. 5, while the p− base concentrations of the emitter end and the collector end were the same in the process of FIG. 4, several process modifications can be applied to achieve different p− base concentrations of the emitter end and the collector end. In (a), the substrate 10 and the n− type epitaxial layer 20 can be formed, and in (b), the p− base region can be patterned for one side region of the semiconductor device on the n− type epitaxial layer 20, and then p type dopant ions can be injected to form the first p type base layer 211. In (c), the second p type base layer 212 can be formed on the n− type epitaxial layer 20 by patterning the p− base region for the other side region of the semiconductor device and then injecting p type dopant ions. In (d), the n+ type layers 231 and 232 can be formed by patterning an n+ region on the p type base layers 211 and 212 and then injecting n type dopant ions, and the p+ type layers 221 and 222 can be formed adjacent to the n+ type layers 231 and 232 within the p type base layers 211 and 212 by patterning a p+ region on the p type base layers 211 and 212 and at the same layer level as the n+ type layers 231 and 232 and then injecting the same p type dopant ions. In (e), the insulating layer 30 can be formed through a gate oxide layer deposition process, and in (f), the gate 31 can be formed through patterning after polysilicon deposition. In (g), the passivation layer 40 can be deposited, and the emitter 50 and the collector 60 can be formed, wherein a portion of the lower surface of the collector 60 can be in contact with the upper surface of the insulating layer 30, and another portion of the lower surface of the collector 60 can be in contact with a portion of the upper surface of the second n+ type layer 232 and the upper surface of the second p+ type layer 222. The gate 31 can be formed to be covered with the passivation layer 40, and the collector 60 can be formed not to be covered with the passivation layer 40.

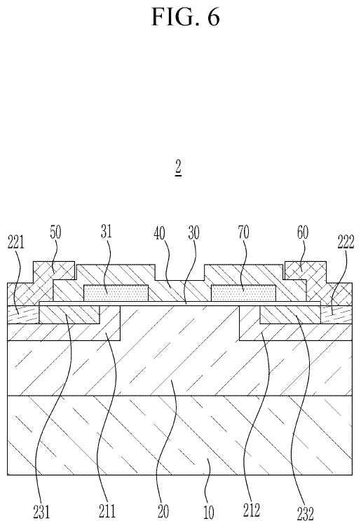

FIG. 6 illustrates a semiconductor device according to an example of the present disclosure.

Referring to FIG. 6, a semiconductor device 2 according to an implementation can include a substrate 10, a n− type epitaxial layer 20, a p type base layers 211 and 212, a p+ type layers 221 and 222, a n+ type layers 231 and 232, an insulating layer 30, a gate 31, a passivation layer 40, an emitter 50, and collectors 60 and 70.

The substrate 10 can be a semi-insulating substrate or an insulating substrate. In some implementations, the semi-insulating substrate can be made of gallium arsenide (GaAs), silicon carbide (SiC), or the like, and the insulating substrate can be made of sapphire, glass, a silicon-on-insulator (SOI) substrate, or the like. The n− type epitaxial layer 20 can be formed on the substrate 10.

The p type base layers 211 and 212 can be formed on the n− type epitaxial layer 20. The p type base layers can include a first p type base layer 211 and a second p type base layer 212. The p type base layers 211 and 212 can be formed by patterning the p− base region on the n− type epitaxial layer 20, then injecting p type dopant ions, such as boron, into the region, and diffusing and activating them through a subsequent heat treatment process.

The n+ type layers 231 and 232 can be formed within the p type base layers 211 and 212. The n+ type layers can include a first n+ type layer 231 and a second n+ type layer 232. The n+ type layers 231 and 232 can be formed by patterning an n+ region on the p type base layers 211 and 212, then injecting n type dopant ions, such as phosphorus and/or arsenic into the region, and diffusing and activating them through a subsequent heat treatment process.

The p+ type layers 221 and 222 can be formed adjacent to the n+ type layers 231 and 232 within the p type base layers 211 and 212. The p+ type layers 221 and 222 can be formed by patterning a p+ region on the p type base layers 211 and 212 and at the same layer level as the n+ type layers 231 and 232, then injecting p type dopant ions, such as boron, into the region, and diffusing and activating them through a subsequent heat treatment process.

The insulating layer 30 can be formed on the n− type epitaxial layer 20. This can be achieved through a gate oxide layer deposition process. The gate oxide layer can be formed of silicon oxide (SiO₂) through a thermal oxidation or chemical vapor deposition process.

The gate 31 is formed on the insulating layer 30, and can be formed on at least a portion of the first p type base layer 211 disposed in one side region of the semiconductor device 2, and on a portion of the first n+ type layer 231 disposed in one side region of the semiconductor device 2. The gate 31 can be formed of polysilicon, and a metal material can be used as needed.

The collector 60 can be formed on the insulating layer 30. The collector 60 can also be formed on at least a portion of the second p type base layer 212 disposed in the other side region of the semiconductor device 2, and on at least a portion of the second n+ type layer 232 disposed in the other side region of the semiconductor device 2.

The p+ type layers 221 and 222 can include a first p+ type layer 221 disposed in one side region of the semiconductor device 2 and a second p+ type layer 222 disposed in the other side region of the semiconductor device 2.

Here, the first n+ type layer 231 can be formed to be disposed between the first p type base layer 211 and the first p+ type layer 221, and the second n+ type layer 232 can be formed to be disposed between the second p type base layer 212 and the second p+ type layer 222.

In some implementations, one side surface of the first n+ type layer 231 can be in contact with the first p+ type layer 221, and the other side surface of the first n+ type layer 231, the lower surface of the first n+ type layer 231, and the lower surface of the first p+ type layer 221 can be in contact with the first p type base layer 211. One side surface of the second n+ type layer 232, the lower surface of the second n+ type layer 232, and the lower surface of the second p+ type layer 222 can be in contact with the second p type base layer 212, and the other side surface of the second n+ type layer 232 can be in contact with the second p+ type layer 222.

The lower surface of the insulating layer 30 can be in contact with a portion of the upper surface of the first n+ type layer 231, the uppermost surface of the first p type base layer 211, the uppermost surface of the second p type base layer 212, and a portion of the upper surface of the second n+ type layer 232.

In some implementations, a portion of the lower surface of an emitter 50 can be in contact with a portion of the upper surface of the first n+ type layer 231 and the upper surface of the first p+ type layer 221.

In some implementations, the gate 31 and the collector 70 can be formed to be covered with the passivation layer 40, and the lower surface of the collector 70 can be in contact with the upper surface of the insulating layer 30.

In addition, in some implementations, the semiconductor device 2 can further include an additional collector 60. A portion of the lower surface of the additional collector 60 can be in contact with the upper surface of the passivation layer 40, and another portion of the lower surface of the additional collector 60 can be in contact with a portion of the upper surface of the second n+ type layer 232 and the upper surface of the second p+ type layer 222.

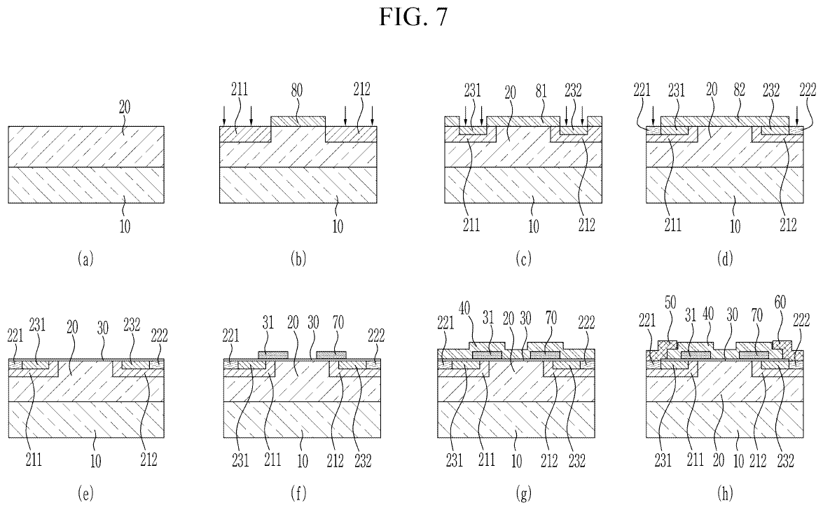

FIG. 7 illustrates a method for manufacturing a semiconductor device according to an example of the present disclosure.

As shown in FIG. 7, in (a), the substrate 10 and the n− type epitaxial layer 20 can be formed, and in (b), the p− base region can be patterned on the n− type epitaxial layer 20, and then p type dopant ions can be injected to form the p type base layers 211 and 212. In (c), the n+ type layers 231 and 232 can be formed by patterning an n+ region on the p type base layers 211 and 212 and then injecting n+ type dopant ions. In (d), after patterning the p+ region on the p type base layers 211 and 212 and at the same layer level as the n+ type layers 231 and 232, the same p type dopant ions are injected so that the p+ type layers 221 and 222 can be formed adjacent to the n+ type layers 231 and 232 within the p type base layers 211 and 212. In (e), the insulating layer 30 can be formed through a gate oxide layer deposition process, and in (f), the gate 31 can be formed through patterning after polysilicon deposition. In (g), the passivation layer 40 can be deposited, and the emitter 50 and the collectors 60 and 70 can be formed, wherein the gate 31 and the collector 70 can be formed to be covered with the passivation layer 40, the lower surface of the collector 70 can be in contact with the upper surface of the insulating layer 30, a portion of the lower surface of the collector 60 can be in contact with the upper surface of the insulating layer 40, and another portion of the lower surface of the collector 60 can be in contact with a portion of the upper surface of the second n+ type layer 232 and an upper surface of the second p+ type layer 222.

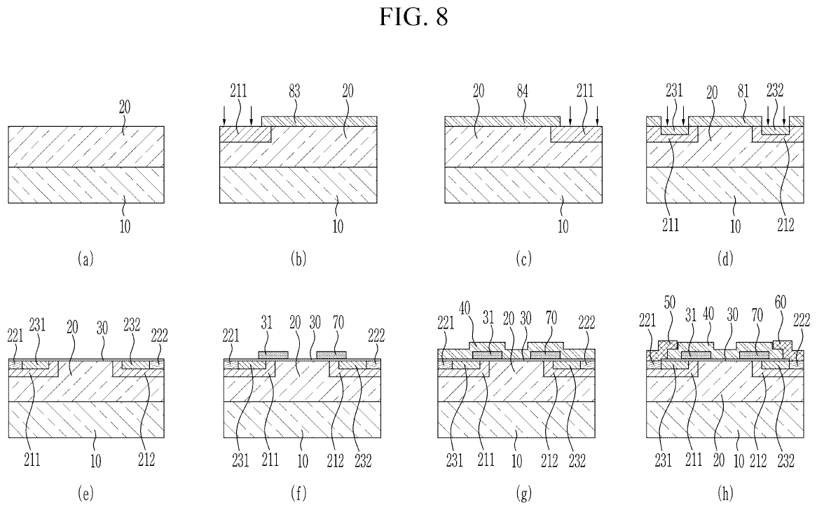

FIG. 8 illustrates a method for manufacturing a semiconductor device according to an example of the present disclosure.

Referring to FIG. 8, while the p− base concentrations of the emitter end and the collector end were the same in the process of FIG. 7, several process modifications can be applied to achieve different p− base concentrations of the emitter end and the collector end. In (a), the substrate 10 and the n− type epitaxial layer 20 can be formed, and in (b), the p− base region can be patterned for one side region of the semiconductor device on the n− type epitaxial layer 20, and then p type dopant ions can be injected to form the first p type base layer 211. In (c), the second p type base layer 212 can be formed on the n− type epitaxial layer 20 by patterning the p− base region for the other side region of the semiconductor device and then injecting p type dopant ions. In (d), the n+ type layers 231 and 232 can be formed by patterning an n+ region on the p type base layers 211 and 212 and then injecting n type dopant ions, and the p+ type layers 221 and 222 can be formed adjacent to the n+ type layers 231 and 232 within the p type base layers 211 and 212 by patterning a p+ region on the p type base layers 211 and 212 and at the same layer level as the n+ type layers 231 and 232 and then injecting the same p type dopant ions. In (e), the insulating layer 30 can be formed through a gate oxide layer deposition process, and in (f), the gate 31 can be formed through patterning after polysilicon deposition. In (g), the passivation layer 40 can be deposited, and the emitter 50 and the collectors 60 and 70 can be formed, wherein the gate 31 and the collector 70 can be formed to be covered with the passivation layer 40, the lower surface of the collector 70 can be in contact with the upper surface of the insulating layer 30, a portion of the lower surface of the collector 60 can be in contact with the upper surface of the insulating layer 40, and another portion of the lower surface of the collector 60 can be in contact with a portion of the upper surface of the second n+ type layer 232 and an upper surface of the second p+ type layer 222.

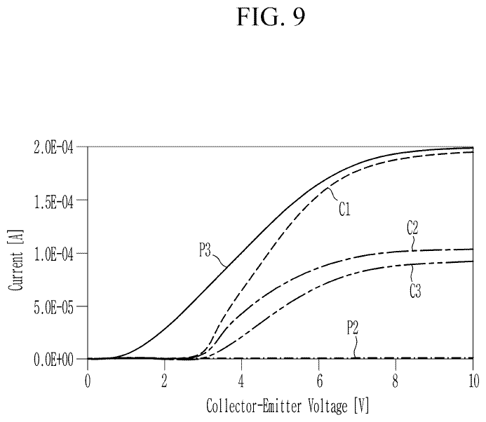

FIGS. 9 to 11 illustrate the characteristics of a semiconductor device according to examples of the present disclosure.

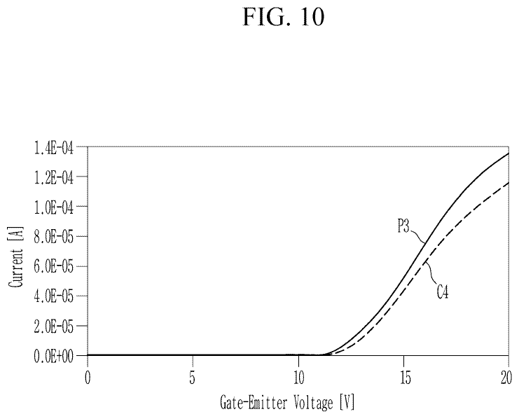

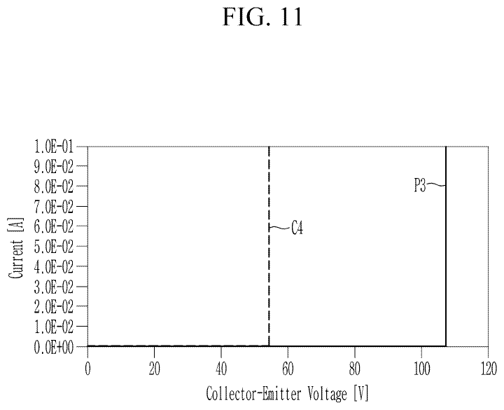

FIG. 9 shows on-state currents of semiconductor devices P2 and P3 according to implementations of the present disclosure compared to on-state currents of comparative semiconductor devices C1, C2, and C3 from the related art, FIG. 10 shows a threshold voltage of the semiconductor device P3 according to an implementation of the present disclosure compared to a threshold voltage of the comparative semiconductor device C4 from the related art, and FIG. 11 shows a breakdown voltage of the semiconductor device P3 according to an implementation of the present disclosure compared to a breakdown voltage of the comparative semiconductor device C4 from the related art. The results performed using Synopsys' Sentaurus TCAD are represented in the following table.

TABLE 1

| | Structure of | Structure of |
|---|---|---|
| Category | implementation | related art |
| Current density [mA/mm] | 134.58 | 119.72 |
| Electron current density [mA/mm] | 134.55 | 49.14 |
| Hole current density [mA/mm] | 0.04 | 70.57 |
| Knee voltage [V] | 0.99 | 2.98 |
| Breakdown voltage [V] | 107.09 | 54.20 |

In summary, the results show that the channel formation in the MOS structure reduces the knee voltage by 66.8%, expanding the on-state operation region and thereby reducing the on-state operation loss. In addition, the current density increases by 12.4%, which reduces the on-resistance, and the proportion of hole (minority carrier) current density in the total current density is suppressed to 0.03%, which reduces minority carrier diffusion current, thereby reducing switching loss and improving switching speed. Additionally, the breakdown voltage increases by 97.6% as the gate electric field concentration phenomenon is alleviated, thereby improving the overall electrical performance of the device.

According to the implementations described so far, aspects of the present disclosure can improve the on-current characteristics, switching characteristics, and breakdown voltage characteristics of the lateral IGBT. Specifically, the structure according to the implementations of the present disclosure can increase the voltage range over which the IGBT can perform on-state operation by reducing the knee voltage of the IGBT using a MOS channel. In addition, aspects of the present disclosure can alleviate the problem of reducing the switching speed of the device by controlling the current caused by minority carriers generated in the on-state, and improve the dynamic characteristics of the device. At the same time, the static characteristics can also be improved by increasing the on-state current. In addition, it is possible to prevent a breakdown phenomenon due to destruction of the gate oxide layer by alleviating the electric field concentrated in the gate corner area adjacent to the collector. Furthermore, since the manufacturing method according to some implementations of the present disclosure is based on an ion implantation process and an epitaxial process, it may not require additional new process technology and can utilize existing semiconductor manufacturing processes, thereby providing highly practical effects.

While the implementations of the present disclosure have been described in detail, it is to be understood that the disclosure is not limited to the disclosed implementations, but on the contrary, is intended to cover various modifications and equivalent arrangements included within the spirit and scope of the appended claims.

What is claimed is:

1. A semiconductor device, comprising:
a substrate;
an n− type epitaxial layer on the substrate;
a first p type base layer on the n− type epitaxial layer and in one side region of the semiconductor device;
a second p type base layers on the n− type epitaxial layer and in the other side region of the semiconductor device;
a first n+ type layers within the first p type base layer and in the one side region of the semiconductor device;
a second n+ type layers within the second p type base layer and in the other side region of the semiconductor device;
a first p+ type layer adjacent to the first n+ type layer within the first p type base layer and in the one side region of the semiconductor device;
a second p+ type layer adjacent to the second n+ type layer within the second p type base layer and in the other side region of the semiconductor device;
an insulating layer on the n− type epitaxial layer;
a gate on the insulating layer, at least a portion of the first p type base layer, and a portion of the first n+ type layer; and
a collector on the insulating layer, at least a portion of the second p type base layer, and at least a portion of the second n+ type layer.

2. The semiconductor device of claim 1, wherein:
the first n+ type layer is disposed between the first p type base layer and the first p+ type layer, and
the second n+ type layer is disposed between the second p type base layer and the second p+ type layer.

3. The semiconductor device of claim 1, wherein
one side surface of the first n+ type layer is in contact with the first p+ type layer, and
the other side surface of the first n+ type layer, a lower surface of the first n+ type layer, and a lower surface of the first p+ type layer are in contact with the first p type base layer.

4. The semiconductor device of claim 1, wherein
one side surface of the second n+ type layer, a lower surface of the second n+ type layer, and a lower surface of the second p+ type layer are in contact with the second p type base layer, and
the other side surface of the second n+ type layer is in contact with the second p+ type layer.

5. The semiconductor device of claim 1, wherein
a lower surface of the insulating layer is in contact with a portion of an upper surface of the first n+ type layer, an uppermost surface of the first p type base layer, an uppermost surface of the second p type base layer, and a portion of an upper surface of the second n+ type layer.

6. The semiconductor device of claim 1, further comprising:
an emitter,
wherein a portion of a lower surface of the emitter is in contact with a portion of an upper surface of the first n+ type layer and an upper surface of the first p+ type layer.

7. The semiconductor device of claim 1, wherein
a portion of a lower surface of the collector is in contact with the upper surface of the insulating layer, and
another portion of a lower surface of the collector is in contact with a portion of an upper surface of the second n+ type layer and an upper surface of the second p+ type layer.

8. The semiconductor device of claim 1, wherein
the gate is covered with a passivation layer, and
the collector is not covered with the passivation layer.

9. The semiconductor device of claim 1, wherein:
the gate and the collector are covered with the passivation layer, and
a lower surface of the collector is in contact with an upper surface of the insulating layer.

10. The semiconductor device of claim 9, further comprising:
an additional collector,
wherein a portion of a lower surface of the additional collector is in contact with an upper surface of the passivation layer, and
wherein another portion of the lower surface of the additional collector is in contact with a portion of an upper surface of the second n+ type layer and an upper surface of the second p+ type layer.

11. A method for manufacturing a semiconductor device, comprising:
providing a substrate;
forming an n− type epitaxial layer on the substrate;
forming a first p type base layer on the n− type epitaxial layer and in one side region of the semiconductor device;
forming a second p type base layer on the n− type epitaxial layer and in the other side region of the semiconductor device;
forming a first n+ type layer on the first p type base layer and in the one side region of the semiconductor device;
forming a second n+ type layer on the second p type base layer and in the other side region of the semiconductor device;
forming a first p+ type layer adjacent to the first n+ type layer within the first p type base layer and in the one side region of the semiconductor device;
forming a second p+ type layer adjacent to the second n+ type layer within the second p type base layer and in the other side region of the semiconductor device;
forming an insulating layer on the n− type epitaxial layer;
on the insulating layer, forming a gate on at least a portion of the first p type base layer and a portion of the first n+ type layer; and
on the insulating layer, forming a collector on at least a portion of the second p type base layer and at least a portion of the second n+ type layer.

12. The method of claim 11, wherein:
the first n+ type layer is disposed between the first p type base layer and the first p+ type layer, and
the second n+ type layer is disposed between the second p type base layer and the second p+ type layer.

13. The method of claim 11, wherein:
one side surface of the first n+ type layer is in contact with the first p+ type layer, and
the other side surface of the first n+ type layer, a lower surface of the first n+ type layer, and a lower surface of the first p+ type layer are in contact with the first p type base layer.

14. The method of claim 11, wherein:
one side surface of the second n+ type layer, a lower surface of the second n+ type layer, and a lower surface of the second p+ type layer are in contact with the second p type base layer, and
the other side surface of the second n+ type layer is in contact with the second p+ type layer.

15. The method of claim 11, wherein:
a lower surface of the insulating layer is in contact with a portion of an upper surface of the first n+ type layer, an uppermost surface of the first p type base layer, an uppermost surface of the second p type base layer, and a portion of an upper surface of the second n+ type layer.

16. The method of claim 11, further comprising:
forming an emitter,
wherein a portion of a lower surface of the emitter is in contact with a portion of an upper surface of the first n+ type layer and an upper surface of the first p+ type layer.

17. The method of claim 11, wherein:
a portion of a lower surface of the collector is in contact with an upper surface of the insulating layer, and
another portion of the lower surface of the collector is in contact with a portion of an upper surface of the second n+ type layer and an upper surface of the second p+ type layer.

18. The method of claim 11, wherein:
the gate is covered with a passivation layer, and
the collector is not covered with the passivation layer.

19. The method of claim 11, wherein:
the gate and the collector are covered with the passivation layer, and
a lower surface of the collector is in contact with an upper surface of the insulating layer.

20. The method of claim 19, further comprising:
forming an additional collector,
wherein a portion of a lower surface of the additional collector is in contact with an upper surface of the passivation layer, and
wherein another portion of the lower surface of the additional collector is in contact with a portion of an upper surface of the second n+ type layer and an upper surface of the second p+ type layer.
